(19) United States
(12) Patent Application Publication
(10) Pub. No.: US 2012/0031470 A1
(43) Pub. Date: Feb. 9, 2012

(54) SOLAR PANEL CONFIGURATIONS

(76) Inventors: Dmitry Dimov, San Francisco, CA (US); Julian Sweet, San Francisco, CA (US); Mark Goldman, Menlo Park, CA (US); Theo Mann, Hermosa Beach, CA (US); Christine M. Kurjan, Seattle, WA (US); Anne Elizabeth, Palo Alto, CA (US)

(21) Appl. No.: 13/133,634

(22) PCT Filed: Jun. 17, 2010
(86) PCT No.: PCT/US2009/067397

§ 371 Date: Oct. 5, 2011

Related U.S. Application Data
(60) Provisional application No. 61/201,536, filed on Dec. 10, 2008.

(51) Int. Cl. H01L 31/048; H01L 23/12; H01L 31/18

(52) U.S. Cl. 136/251; 29/890.033; 211/41.1

(57) ABSTRACT

The invention provides solar panel systems, which may be applied to surfaces such as residential rooftops. The invention also provides methods of installing solar panel systems. A solar panel system may comprise one or more module, which may comprise one or more solar panels and a rack. A solar panel may comprise a polymer, and may not comprise glass or a metal frame. The rack may include three footings and a plurality of adjustable fasteners that may enable the module to reside on an uneven surface. The rack may also include integrated electronic components and a microinverter. A module may yield a desired power output, and may generate performance monitoring data.

### CROSS REFERENCE

This application claims the benefit of priority to U.S. Provisional Patent Application No. 61/201,536 filed on Dec. 10, 2008, which is incorporated herein by reference in its entirety.

### BACKGROUND OF THE INVENTION

Residential solar photovoltaic systems have been an area of significant interest and investment. However, a review of the current installed base presents a sobering picture. The approximately 60,000 grid-connected residential solar PV systems constitute less than 1/10th of 1% of the total number of residential roofs in the US, estimated at 100 million.

In particular, there are several barriers to wide deployment of residential solar PV systems, including: high installation and overhead costs where total installed system costs for an average system are too high for most US households, a long and complicated process of procuring a residential solar system that cannot scale to meet higher demand, a scarcity of specialized skills required for solar PV installations, and low consumer satisfaction with aesthetics of PV installations.

Cost has been a major barrier to residential solar PV system adoption. Although the reductions in cost have been dramatic over the last two decades, solar panels that use crystalline silicon cells—the dominant type today at 96% of the market—cost between $4 and $6 per Watt. The total cost of an installed residential solar PV system is nearly $10 per Watt. The balance of system, labor, and overhead costs are a significant portion of the installed system price. The lengthy and complicated process of selling and installing residential solar PV systems contributes to the high cost of solar and significantly inhibits adoption. At $10 per Watt installed, the average residential solar PV system of 4.7 kW DC costs $47,000 to the consumer. The Federal tax credit and state and local incentives such as CSI rebates may bring the cost down to $26,000. Nevertheless, even this lower figure is a significant capital outlay for a residential customer and represents a major buying decision, and the above sum is out of reach for most consumers.

Furthermore, solar installation is a very scarce skill set. A successful solar installation that passes inspections and qualifies for incentives requires significant specialized expertise. Today's solar installation process includes steps such as bill analysis, site surveying, shading analysis, financial modeling, engineering drawings, permit applications, solar equipment selection and matching panels and inverters, electrical system design, roof attachment work, rack and panel installation, grounding and DC wiring, electrical interconnect, and tax rebate paperwork processing. This puts it out of reach of most individual contractors. The recent trend in the solar industry has been towards installer companies of larger size capable of assembling this diverse skill set, as exemplified by companies such as SolarCity, as well as towards large vertically integrated concerns, such as SunPower. The issue with availability of skilled solar installers becomes more apparent when the number of solar installers is compared with the number of other skilled tradespeople, such as electricians or HVAC specialists.

Moreover, many consumers consider a typical solar PV installation aesthetically unattractive. The poor appearance of a typical system may contribute to dampening consumer demand for solar. Many consumers have the “set it and forget it” mentality for their rooftop PV systems: within a few months after the installation many forget about it and are occasionally reminded of their systems when they closely examine their electric bills. Few consumer purchases of this magnitude share this characteristic. The lack of enthusiasm and pride of ownership cannot be helpful for increasing public interest in residential solar systems.

Attempts have been made to improve rooftop residential solar systems. For instance, one attempt utilizes panels that are modular, yet designed to attach together as an integrated system. See, e.g., U.S. Patent Publication No. 2007/0295392 and U.S. Patent Publication No. 2007/0295393, which are hereby incorporated by reference in their entirety. All racking hardware, grounding wires, wiring connections—even the connections between panels—are integrated. While the high level of system integration represents an improvement, the installation process remains similar to traditional systems: the system must be sized and matched to the inverter, the roof attachments must be accurately laid out on the roof in advance, inverter installed on the side of the building and DC wiring run from the array to the inverter. In addition, the low panel clearance required by the design reduces the system rating for rebate purposes.

Another attempt relates to a residential system for sloped composite shingle roofs. A metal track with an integrated AC bus is nailed to the roofing deck. Panels with microinverters snap into the track, and the AC cables plug into electrical receptacles in the track. Some challenges arising from this design include sufficient strength of roof attachment to resist wind loading, and low tolerance to uneven roofs.

Therefore, a need exists for a residential solar system that may allow for simplified installation. Further need exists for a residential solar system that may have a design that may enable it to be placed on a variety of roof surfaces or configurations.

### SUMMARY OF THE INVENTION

The invention provides solar panel systems and modules with various configurations. The invention further provides a rack and support system that may allow simplified installation and electrical connections. Various aspects of the invention described herein may be applied to any of the particular applications set forth below or for other types of energy generation or transfer systems. The invention may be applied as a standalone system or method, or as part of an application, such as providing module electrical support components. It shall be understood that different aspects of the invention can be appreciated individually, collectively, or in combination with each other.

The invention provides a solar panel system. The solar panel system may be adapted to residential rooftops or to other situations where a photovoltaic (PV) solar panel may be utilized. Preferable embodiments of the invention may be applied to sloped composite shingle roofs, while the solar panel configurations may also address other roofing materials or configurations, such as tile, flat roofs, and pole mounts.

The solar panel system may comprise one or more modules, which may each comprise a plurality of solar panels placed on a rack. In some instances, the solar panel system may comprise three modules. Preferably, a module may comprise three hexagonal solar panels, placed on a triangular rack. Each module may include a microinverter and may produce standard AC output suitable for direct interconnect with the utility grid. Each solar panel may comprise solar cells such as high-efficiency monocrystalline silicon solar cells. The panels may be built from structural plastic and have no glass or metal frame.

Each module's rack may have three fixed footings that can rest on a roof surface, and adjustable fasteners for securing the system to the roof. Three-point footing may ensure stability on uneven roofs, and the fasteners can be moved for optimal attachment to roof rafters or decking. This rack configuration may enable an innovative roof attachment method.

Each solar panel system may generate performance data, which may be reported through an online performance monitoring dashboard.

Advantages of the solar panel system may include:

1. Small, standard size. A system may produce 1 kW AC. The power output may be the minimum size that qualifies for typical state and federal incentives. This system size may allow for reduced total system cost and installation time, while still offsetting a meaningful percentage of peak electricity usage. The small, standard size may also eliminate the need for detailed system sizing and design for most households, which may streamline the procurement process.

2. Fully integrated mechanical and electrical design. All system components, including panels, rack, roof attachment, and power electronics may be designed as a unit. This may dramatically simplify system assembly and installation, and significantly reduces the need for specialized solar installer skills.

3. Integrated microinverter. The system may include an integrated microinverter for DC-to-AC conversion and Maximum Power Point Tracking (MPPT) optimization. This may result in improved system efficiency compared to traditional inverters, and may eliminate the need for power electronics and DC wiring expertise.

4. Innovative installation and roof attachment method. The system may be designed in accordance with reduced constraint design principles. In particular, the system can be installed on uneven roofs or unusual roof configurations more easily, and the process of attaching it to the roof may be easier compared to traditional installations.

5. Low weight, glassless, frameless panels. Glassless, frameless panels may use innovative materials, such as ethylene tetrafluoro ethylene (ETFE) and high stiffness structural plastic, to achieve lower weight. This may reduce shipping costs and carbon footprint, reduce breakage, and allow for safer and easier handling. In the event of an earthquake or hurricane, the absence of glass and the reduction in panel weight may serve to reduce human and property damage. In addition, the panels may have no exposed metal parts and require no grounding, which may improve safety and simplify installation.

Large-scale commercialization of the solar panel system may directly benefit the following constituencies:

US Federal Government Agencies, such as the National Park Service. The Department of Interior and Department of Energy recently announced their intent to “help the National Park Service (NPS) showcase sustainable energy practices and fulfill its mission of environmental stewardship.” The small standard size of the solar panel system, its high degree of integration, and simplicity and versatility of installation may make it suitable for deployment on NPS facilities by NPS's own personnel with only basic electrical and home repair experience, but with no special solar training. In general, the ability to deploy the solar panel system quickly and with minimal training may make it an attractive option for helping government agencies reach their own internal renewable portfolio standards.

Consumers. All-in-one packaging with low total cost and fast installation may make the system more accessible to a broader range of consumers, compared to traditional residential solar systems. The small, standard size may mean simpler pre-qualification requirements and fewer sales visits needed today for correct system sizing. Finally, the system's innovative shape and aesthetic appeal will help increase consumer interest and owner satisfaction.

Installers. The solar panel system may enable the large numbers of electricians and other home repair professionals, such as roofers, HVAC specialists, and plumbers, to enter the residential solar market more easily. The fully integrated package with grid-compatible output and simple installation can reduce the learning curve for these new entrants into the solar industry. At the same time, skilled solar installers may be able to service the low end of the market of customers, and may be able to install the system faster and with fewer quality problems. In addition, because each system installation may follow the same configuration, the paperwork burden on installers for permitting and rebate approval may be reduced.

Electric Utilities. Because of its low price point and simpler installation, the solar panel system can be deployed to larger numbers of utility customers, across a more distributed geographic area, and in a shorter period of time. While traditional solar PV installations aim to offset a large portion of customer's energy usage, the solar panel system provided by the invention may reduce peak power consumption, and may therefore be better aligned with utilities' priorities to reduce peak load while keeping the utility grid stable. Utility companies prefer grid-connected PV to be highly distributed in order to alleviate unequal loading of the grid.

Municipalities and local governments. Even with the small number of solar installations today, municipalities are struggling to keep up with permit and rebate approval paperwork, since each installation is unique. The situation will get worse as the volume of permit and rebate applications increases, while budgets remain tight. The standard packaging of the solar panel system means that permitting and rebate paperwork can be streamlined.

Other goals and advantages of the invention will be further appreciated and understood when considered in conjunction with the following description and accompanying drawings. While the following description may contain specific details describing particular embodiments of the invention, this should not be construed as limitations to the scope of the invention but rather as an exemplification of preferable embodiments. For each aspect of the invention, many variations are possible as suggested herein that are known to those of ordinary skill in the art. A variety of changes and modifications can be made within the scope of the invention without departing from the spirit thereof.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings of which:

FIG. 1A shows a top view of a solar module in accordance with one embodiment of the invention.

FIG. 1B shows a bottom view of a solar module in accordance with one embodiment of the invention.

FIG. 1C shows a top view of a solar module.

FIG. 1D shows a bottom view of a solar module.

FIG. 1E shows a side view of a solar module.

FIG. 1F provides a perspective view of a solar module.

FIGS. 1G-1M shows additional views of a solar module.

FIG. 2 shows a solar panel system with a plurality of modules.

FIG. 3 shows an example of an energy offset by a solar panel system.

FIG. 4 shows an example of an arrangement of solar cells on a solar panel.

FIG. 5 shows an example of a solar installation process.

FIG. 6A shows an example of a rack design with three footings.

FIG. 6B shows another example of rack design on an uneven surface.

FIG. 7 shows an example of a rack placed on a roof with underlying rafters.

FIG. 8A provides an example of a fastener.

FIG. 8B provides an example of an alternate fastener.

FIG. 8C shows an example of a bracket fastener.

FIG. 8D shows a side view of a bracket fastener.

FIG. 9 shows examples of microinverters.

FIG. 10A shows an example of a rack with a plurality of rack sections.

FIG. 10B shows a close up of a corner split plug.

FIG. 10C shows how a panel may attach to a rack in accordance with one embodiment of the invention.

FIG. 11 shows the breakdown of weight of a traditional solar panel.

FIG. 12 shows a cross section of a solar module with an example of wind flow.

### DETAILED DESCRIPTION OF THE INVENTION

While preferable embodiments of the invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention.

The invention provides a solar panel system comprising one or more modules. A module may comprise one or more solar panels, a rack or support, and a microinverter attached to the rack. The solar panel system may be adapted to a residential rooftop or any other surface.

I. Basic Configuration

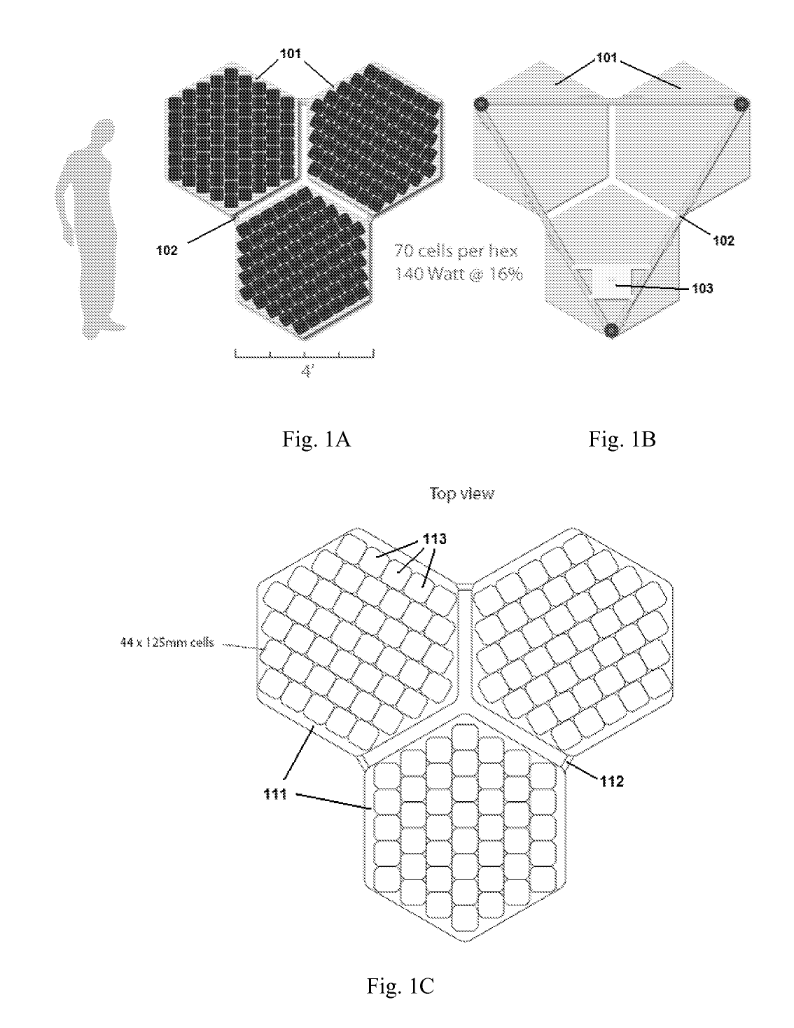

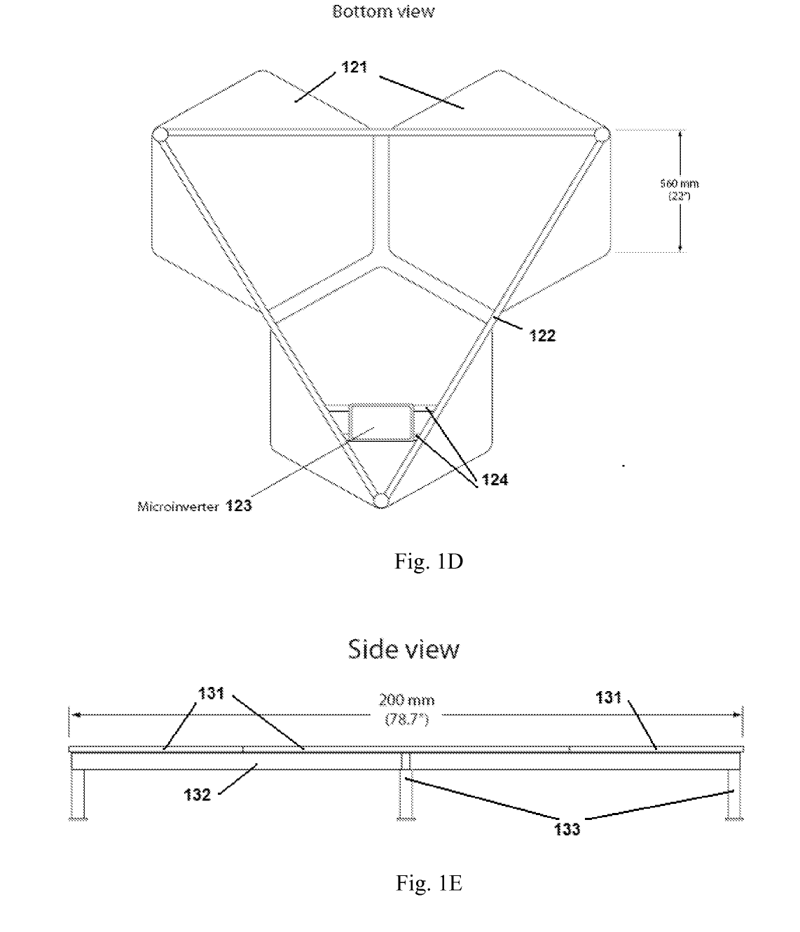

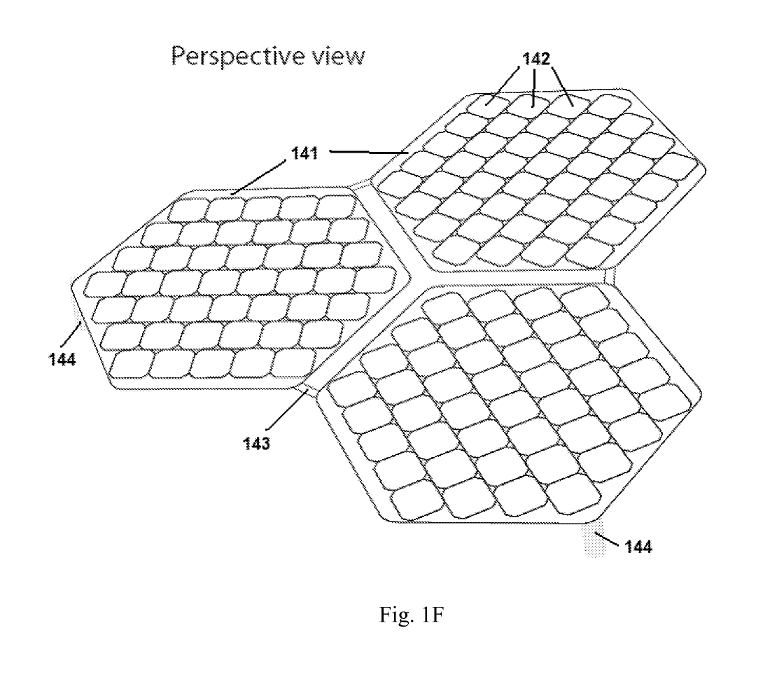

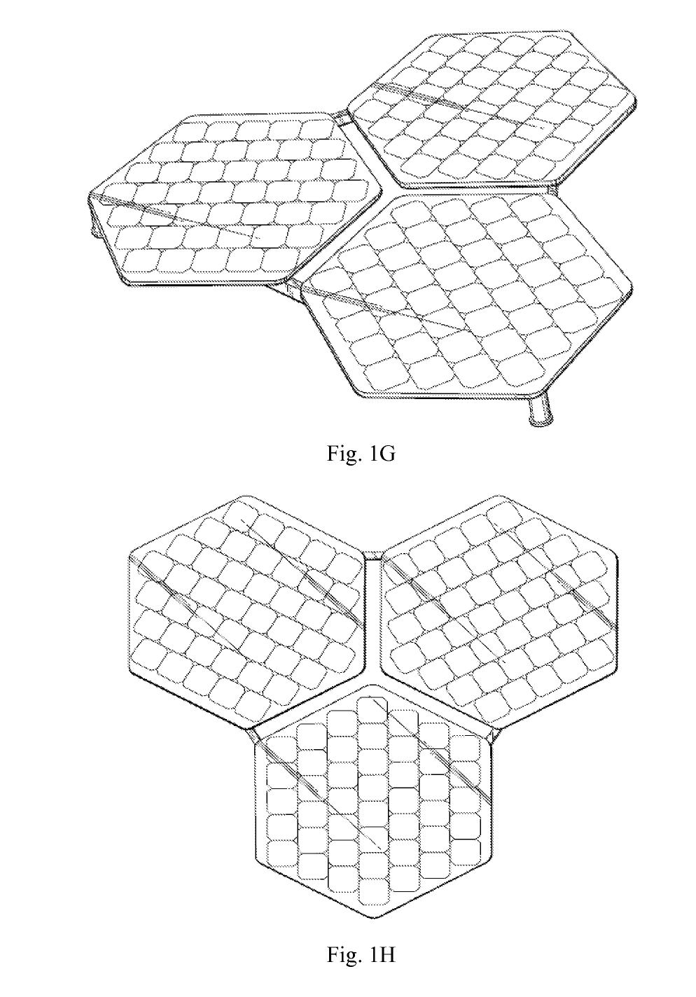

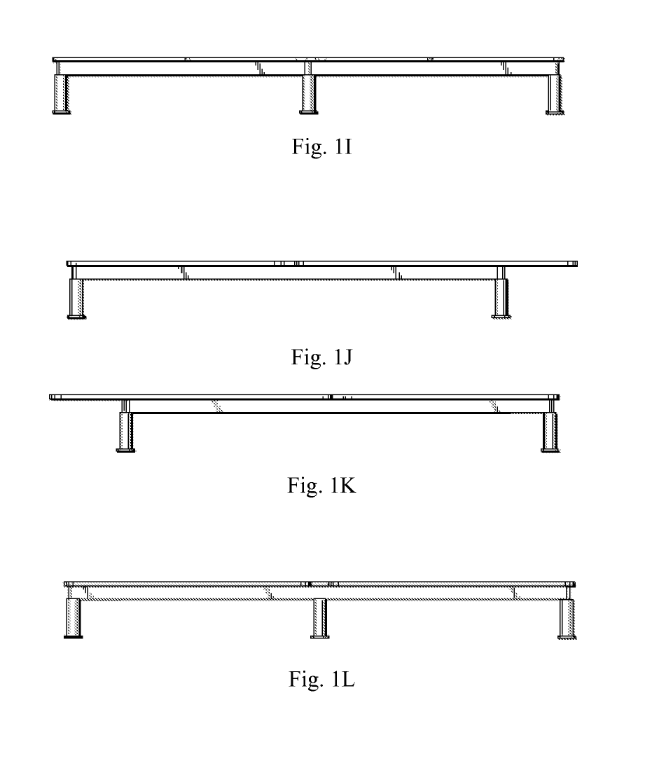

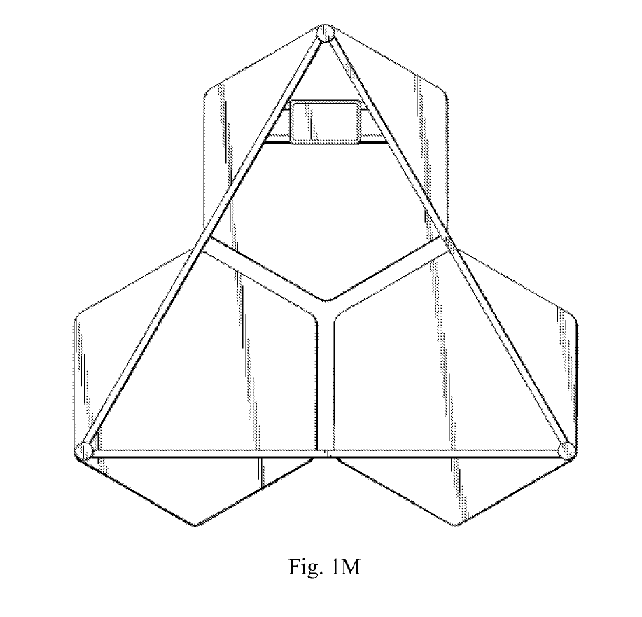

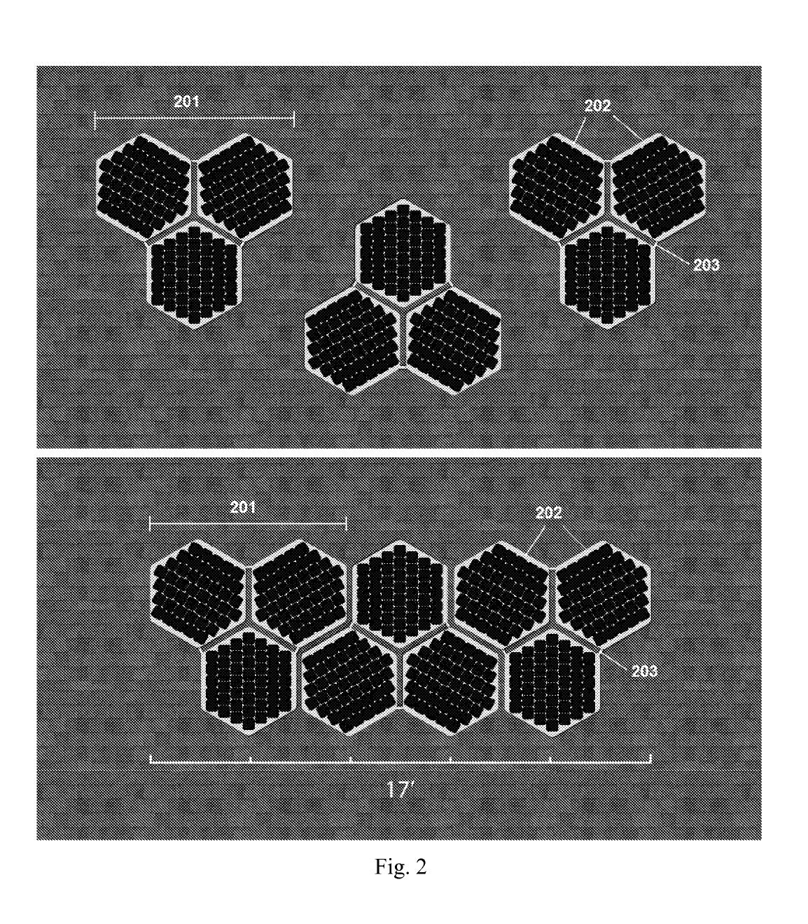

FIG. 1A shows a top view of a module in accordance with one aspect of the invention. FIG. 1B shows a bottom view of the module. A module may include any number of solar panels 101 on a rack 102. A module may also include a microinverter 103 or any other features to connect the module with a utility grid. In one example, a module may comprise three solar panels 101 placed on a rack 102. A module may have a “clover” configuration, such as a configuration where three hexagonal solar panels are combined with a triangular rack.

In some embodiments, the solar panels may have a hexagonal configuration. In other embodiments of the invention, the solar panel may have any shape. For example, the solar panel may be a quadrilateral such as a square or rectangle, or may be a triangle, pentagon, circle, octagon, or any other polygon, or any shape which may be regular or irregular. See e.g., U.S. Pat. No. 6,341,454, which is hereby incorporated by reference in its entirety.

In a preferable embodiment of the invention, all of the solar panels within a module may have the same shape. Alternatively, the solar panels of a module may have different shapes. The solar panel shape may be designed to allow a preferable placement of the solar panel on the rack. For example, the solar panel shapes may be selected to enable the solar panels to be close-fitting when placed on the rack. For example, three hexagonal solar panels may be placed on a triangular rack.

In preferable embodiments of the invention, the solar panels may be arranged on the module so that they are aligned to be coplanar and flat. In other embodiments of the invention, the solar panels may be arranged in a module such that they are parallel to one another but are not all within the same plane. The solar panels may or may not overlap one another. In another embodiment of the invention, the solar panels in a module may be tilted at an angle with respect to one another. In some embodiments, solar panels may be tilted to form three-dimensional features, such as a plurality of solar panels connected or arranged to form a substantially dome shape. Solar panels may have any arrangement with respect to one another. Furthermore, the solar panels may be substantially parallel to a surface the module is attached to, or may be at one or more angles with respect to the surface.

Each solar panel may comprise a plurality of solar cells, such as photovoltaic (PV) solar cells. The panels may include any type of solar cell known or later developed in the art. Some examples of solar cells include, but are not limited to, silicon cells such as monocrystalline silicon solar cells, poly- or multicrystalline silicon solar cells, thin film cells (which may include amorphous silicon, protocrystalline silicon, or nanocrystalline or microcrystalline silicon); cadmium telluride (CdTe) solar cells; copper-indium selenide (CIS) solar cells; copper indium gallium selenide (CIGS) solar cells; dye-sensitized solar cells; or organic or polymer solar cells. Also, some cells may comprise indium gallium phosphide, gallium arsenide, indium gallium arsenide, and/or germanium, and may be fabricated on a germanium substrate, a gallium arsenide substrate or an indium phosphide substrate.

Preferably, the solar cells on a solar panel may all be the same type of solar cell, although in alternative embodiments, multiple types of solar cells may be used in combination. Similarly, each of the panels in a module may include the same types of solar cells, while in other embodiments, each panel may have different solar cells or configurations or arrangements or dimensions.

Any number of solar cells may be arranged on a solar panel. For example, in one embodiment of the invention, 44 high-efficiency monocrystalline silicon solar cells may be included on a solar panel. In another embodiment of the invention, 70 solar cells may be included. In some implementations, the number of solar cells included may fall within a range of solar cells including, but not limited to, 40 to 50 solar cells, 30 to 60 solar cells, 20 to 80 solar cells, 10 to 100 solar cells, or 4 to 200 solar cells. Preferably, each solar panel of a module may have the same number of solar cells, while in other embodiments the number of solar cells may differ.

As discussed elsewhere herein, dimensions and solar cell configurations on solar panels may vary. In one example, a solar panel may be a hexagon with a 560 mm (22″) side, and a 970 mm (38″) width. A solar module may have an approximately 2010 mm (79″) by 2010 mm (79″) set of dimensions. These measurements are provided by way of example only and any other dimensions may be used.

FIG. 1C shows a top view of a module in accordance with one embodiment of the invention. The module may include a plurality of solar panels 111, a rack 112, and a plurality of solar cells 113 on the solar panels 111. The solar cells may have any configuration on a solar panel. For example, they may be arranged in rows such that the solar cells are staggered with respect to the solar cells in the adjacent row. In another example, the solar cells may form an array of cells with rows and columns. The solar cell arrangement may be adapted to the shape of the solar panel. The solar cells may be closely packed to cover a desired amount of surface area on the top of the solar panel. Alternatively, the solar cells may be more loosely packed and spaces may be provided between solar cells.

The solar cells may have any dimension that may enable it to fit on a solar panel. For example, a solar cell may be a 125 mm solar cell. Solar cells may also have any desired shape. For example, solar cells may be substantially rectangular or square. In other embodiments, solar cells may be hexagons, pentagons, triangles, circles, or any other shape. In some embodiments solar cell shapes may be selected to cover a desired amount of surface area of a solar panel. In some embodiments, the solar cells on a solar panel may all have the same shape, while in other embodiments, they may have different shapes to cover the desired amount of surface area. See e.g., U.S. Pat. No. 4,089,705, which is hereby incorporated by reference in its entirety.

Solar panels may be built from any material known or later developed in the art. In some embodiments of the invention, the panels may be formed from structural plastic and may have no glass or metal frame, to be discussed in greater detail below. Alternatively, traditional solar panels that may include glass and/or frames may be used.

A solar panel may have any dimension. In some embodiments, a solar panel may be approximately four feet in diameter. In another embodiment, the solar panel may have a dimension of about three feet. The solar panel may have a diameter or dimension that may fall within one of the following ranges: two feet to six feet, three feet to five feet, or 3.5 feet to 4.5 feet. Depending on the shape of the solar panel, the various dimensions may vary.

In a preferable embodiment of the invention, all of the solar panels within a module may have the same dimensions. Alternatively, the solar panels within a module may not have the same dimensions. A module may have any dimension. For example, a module may be approximately 79 inches across. Alternatively, a module may be approximately 8 feet across. A module may have any dimension across, including, but not limited to, dimensions falling within the range of 70 to 90 inches across, 60 to 120 inches across, 50 to 150 inches across, 30 to 200 inches across, or 20 to 250 inches across.

FIG. 1D shows a bottom view of a solar module in accordance with one embodiment of the invention. A module may include a plurality of solar panels 121, a rack 122, and a microinverter 123. A rack may have any shape or dimension. In a preferable embodiment of the invention, a rack may have a triangular shape. A rack may be formed of three sides. In some instances, the rack may be an equilateral triangle. In other embodiments, the lengths of the sides of the rack may vary, such that the rack may be an isosceles triangle or a scalene triangle. The triangular rack may have any angles. For example, the rack may include angles that are all approximately 60 degrees. Alternatively, the rack may include a right angle, or an obtuse angle, or may be formed of all acute angles.

In other embodiments of the invention, the rack may have any other shape known in the art. For example, the rack may have a rectangular shape, a square shape, a diamond shape, or may be a pentagon, hexagon, or octagon, or circle, or may be a polygon or any other regular or irregular shape. The sides of the rack may all have the same length or may have different lengths.

In some embodiments, the rack configuration may be adjustable. For example, one or more sides of the rack may have an adjustable length. A length of a rack may be adjusted by any means known in the art including, but not limited to, sliding and tightening a portion of the side, incrementally adding or removing a portion of the side, placing a portion of a side into a predetermined length and locking it. See e.g., U.S. Patent Publication No. 2008/0210221, which is hereby incorporated by reference in its entirety. One or more angles of the rack may be adjustable as well, which may accommodate the change in the length of a side, or which may be used to change the shape of the rack without changing dimensions (e.g., a square can be changed to form a rhombus). In some embodiments, the angles may not be adjustable, but the lengths of the sides may be adjustable; for example, the overall dimensions of an equilateral triangle may be increased or decreased without adjusting the angles. In some embodiments, the rack configuration may be fixed, and no parts may be adjustable.

In some embodiments, each module's rack may have fixed footings that rest on a surface, such as a roof surface, and adjustable fasteners for securing the rack to the surface. In a preferable embodiment of the invention, the rack may have three fixed footings. A rack may have three footings whether a rack is a triangular rack or a rack with another shape. Three-point footing may provide stability on uneven roofs. In a preferable embodiment of the invention, the footings may be located at or near the angles of a triangular rack.

FIG. 1E shows a side view of a module in accordance with one embodiment of the invention. The module may include a plurality of solar panels 131, and a rack 132 with footings 133. In a preferable embodiment of the invention, the footings may be fixed on the rack. The footings may be fixed in location on the rack and in length.

Alternatively, the length of the footings may be adjustable, which may allow the module to have a desired tilt. In some embodiments the length of the footings may be adjustable by a small amount, while in other embodiments, the length of the footings may be adjusted by a larger amount (e.g., by more than one inch, by more than three inches, or more than six inches). In another alternate embodiment of the invention, the location of the footings on the rack may be adjustable. For example, the footing may slide along a side of the rack and then be fixed to a desired spot. The footing may be fixed to the desired place on the rack by a mechanical fastener, pin, clamping mechanism, adhesive or other way of affixing a structure known in the art.

The fasteners of a module may be adjusted as desired, to be discussed in greater detail below.

Each module may include a microinverter 123 and may produce standard AC output suitable for direct interconnect with the utility grid. Alternatively a microinverter may be provided per system and a plurality of modules may be interconnected to utilize the microinverter. Descriptions of integrated microinverters are provided in greater detail below.

FIG. 1F shows a perspective view of the module in accordance with one embodiment of the invention with solar panels 141 including solar cells 142, and a rack 143 including footings 144.

FIGS. 1G-1M show additional views of a solar module. For example, FIG. 1G shows a perspective view of a solar module. FIG. 1H shows a top view of the solar module. In some embodiments of the invention, a front of a solar module may be defined as a side of a solar module where a footing may be foremost. A front, or any other orientation, may be provided as a reference, by way of example only, and will not limit the orientations that a solar module may be placed or installed. FIG. 1I shows a front view of the solar module in accordance with one embodiment of the invention. FIG. 1J shows a side view of the solar module (which may be the right side when facing the front of the solar module). FIG. 1K shows a back view of the solar module. FIG. 1L shows a side view of the solar module from the other side (which may be the left side when facing the front of the solar module). FIG. 1M shows a bottom view of the solar module.

FIG. 2 shows a solar panel system in accordance with one embodiment of the invention. A system may include one or more modules 201. For example, in a preferable embodiment of the invention, a system may include three modules 201. Each module may include a plurality of solar panels 202, and a rack 203. Any number of modules may be included in a solar panel system, including but not limited to 2 modules, 3 modules, 4 modules, 5 modules, 6 modules, 8 modules, 10 modules, 12 modules, 15 modules, or 20 modules. A solar panel system may have a fixed number of modules, or the number of modules may vary from one implementation of the system to another implementation.

A plurality of modules in a system may be arranged in any configuration. Such a configuration may be provided on a composite shingle roof, or any other type of roof of surface. Each module can be placed individually depending on the roof configuration, optimum sun exposure, aesthetic preferences or any other factors. In some embodiments, modules in a solar panel system may be placed on a same region or side of a roof, while in other embodiments the modules may be placed anywhere on a structure.

In some embodiments, the modules may be spaced apart. The modules may or may not have the same orientation. For example, in an implementation with three modules, two of the modules may be arranged so that its shape as seen from the top may have a first orientation, while the other module may have a second orientation. In some embodiments, the second orientation may the first orientation rotated a predetermined number of degrees, such as 60 degrees, 90 degrees, 180 degrees, or any number of degrees falling within 0 to 360 degrees.

In another example, the modules may be packed closely together. For example, three modules may be placed adjacent to one another, such that they form a rough honeycomb structure. The modules may be oriented in any direction that allows for the close packing of modules. In some embodiments, the module orientation may depend on the shape of the solar panels.

For example, the modules may be closely packed such that three modules are adjacent to one another in a row, such that they appear to form two rows of solar panels (e.g., hexagonal panels). For example, For example, a first solar module may be adjacent to a second solar module whose orientation is 180 degrees with respect to the first solar module. A third solar module may be adjacent to the second solar module on a side opposite the first solar module, and the third solar module may be oriented 180 degrees with respect to the second solar module. In some embodiments, the length of such a system may be approximately 17 feet. In another embodiment, the length may be approximately 20 feet. The length of the system may depend on the dimensions of the modules, which may vary as discussed previously.

The modules may also be closely packed in other configurations. For example, if there are three modules, they may be close packed so that they form a less linear shape. For example, if modules include hexagonal panels, they may be placed adjacent to one another along any sides where they hexagons may fit in together. Any number of modules may be provided.

In some embodiments, a solar panel system may communicate with a control and/or monitoring system. The solar panel system may generate performance data, which may be reported through an online performance monitoring dashboard. Such performance data may include power outputs for individual modules and/or solar panels. An online performance monitoring dashboard may also provide alarm or alert systems that may notify a user when there is a condition in a module that a user should be aware of, such as an error, a module that is not producing enough power, or a component that is overheating.

In some embodiments, one solar panel system may be included per installation. Alternatively, multiple systems may exist in an installation. The solar panel configurations of the system may be used in any situation where solar energy is being collected. In a preferable embodiment, the solar panel configurations may be used in a residential rooftop installation. For example, the solar panel configurations may be adapted to sloped composite shingle roofs. The solar panel configurations may also be adapted to other roofing materials or styles, such as tile, flat roofs, and pole mounts. The solar panel configurations may also be adapted to other surfaces, including but not limited to building sides, various types of structures or infrastructure (e.g., bridges, roads, towers, etc.), or natural surfaces such as ground.

II. Power Output

A solar panel module or system may have a desired system output. For example, in accordance with some embodiments of the invention, a system output may be 1260 W DC, or approximately 1000 W AC after a typical derating for inverter efficiency and system installation. An output per module may be approximately 334 W AC. In some cases, the desired system output may be the minimum system size or close to the minimum system size eligible for rebates or programs, such as a rebate from the California Solar Initiative (CSI).

In other embodiments of the invention, other desired system outputs may be implemented. For example in accordance with some embodiments of the invention, a system may have an output that falls within 900-2000 W AC, 950-1500 W AC, or 1000-1100 W AC.

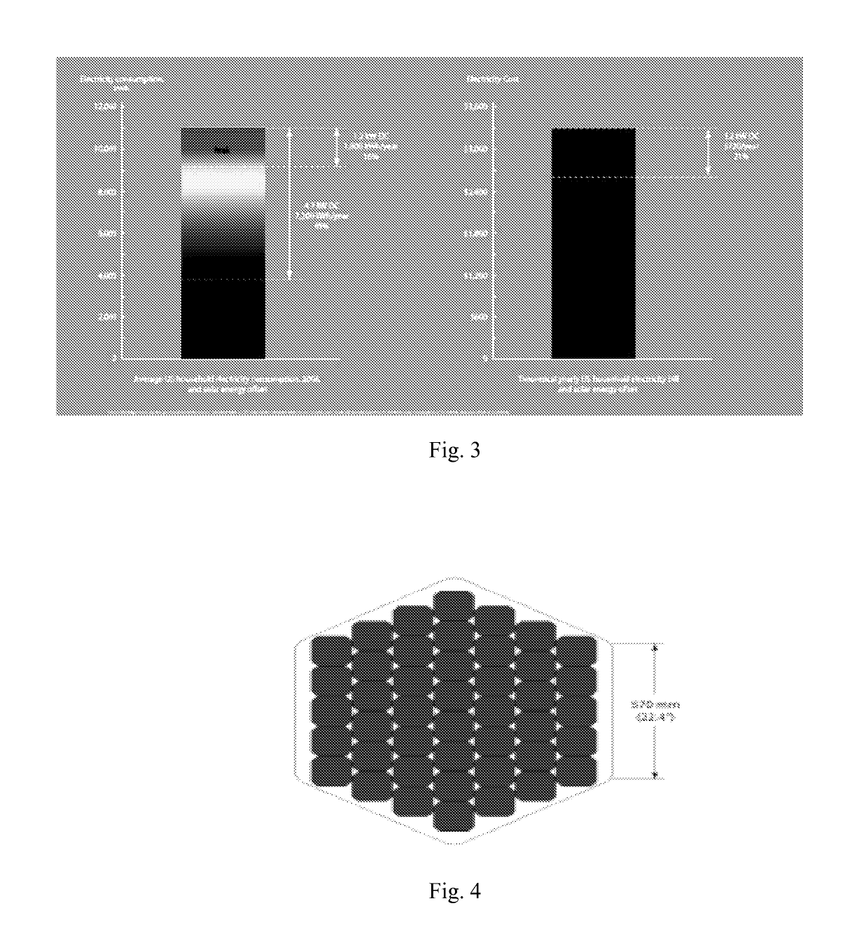

Currently, residential solar systems are usually sized to offset 60 to 80 percent of a household's electricity consumption. A 1 kW AC system may be designed to offset the top 15-20% of typical consumption. FIG. 3 shows an example of an estimated energy offset by using the solar panel system in kWh and dollar amounts.

In order to produce a desired power output, the system may produce a higher DC output to account for losses in the power electronics subsystem, and design factors such as tilt and azimuth. A typical California Energy Commission (CEC) AC derating may vary between 83% and 77%. A system comprising three modules with three panels at approximately 140 W DC each could total 1260 W DC, or 1 kW AC with a 79% derating factor.

A 140 W DC output, or other desired power output per panel, may be achieved by using a plurality of solar cells. For example, 44 standard-sized 125 mm high-efficiency monocrystalline silicon cells, such as those manufactured by SunPower and used in the SunPower 230 W panel, may be arranged in a pattern on a solar panel, such as that illustrated in FIG. 4. As discussed previously, any number or types of photovoltaic cells may be arranged in a predetermined configuration to yield a desired power output for the panel. The number of PV cells may depend on the type of PV cell or configuration of PV cell to achieve a desired power output.

In some embodiments, the shape and arrangement of cells and/or panels may affect the power output. If desired, the solar panel shape and solar cell shape may be selected to produce the desired power output (e.g., a hexagonal solar panel may be covered with hexagonal solar cells, or a combination of cells of various shapes to maximize power-to-area ratio). In another example, the solar cells may have a rectangular configuration, while a solar panel may have a polygonal shape, such as a hexagon. There may be a slight inefficiency in using rectangular cell packing in a hexagonal shape, which may result in a approximately 9% lower power-to-area ratio, compared to a rectangular panel using the same cells. A small reduction in power density may not be very detrimental in a system with a small total size. Any detriments may be offset by benefits provided by an innovative roof attachment technique enabled by the shape and/or other benefits of the shape.

III. Roof Attachment Technique

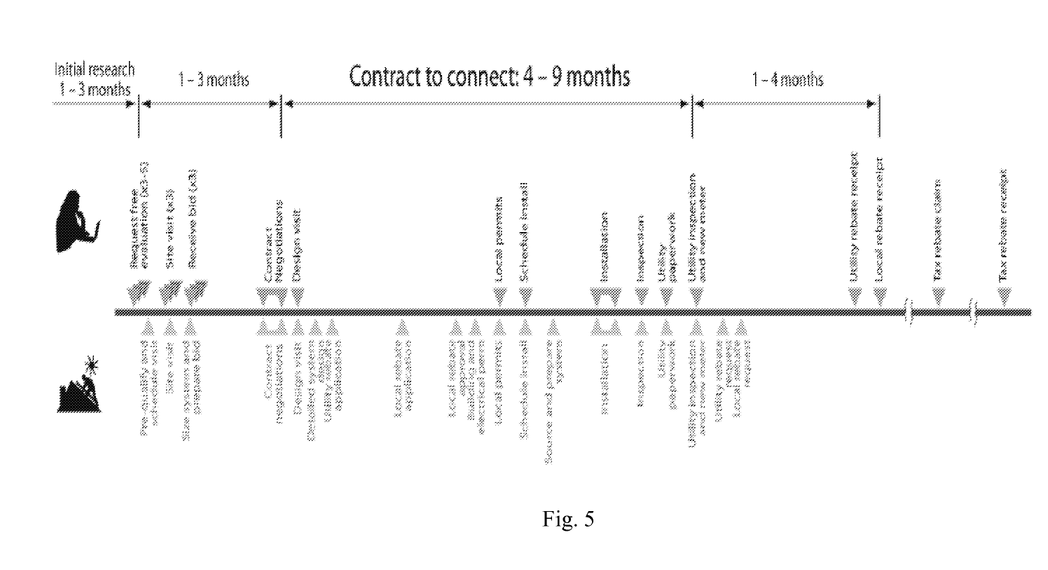

In traditional systems, an overall solar installation process may be a lengthy and complex process. FIG. 5 illustrates one example of a solar installation process. For example, the steps for a consumer may include: request free evaluation (may occur several times), site visits (may occur several times), receive bid (may occur several times), contract negotiations, design visit, local permits, schedule install, installation, inspection, utility paperwork, utility inspection and new meter, utility rebate receipt, local rebate receipt, tax rebate claim, and tax rebate receipt. The steps for an installer may include: pre-qualify and schedule visit, site visit, size system and prepare bid, contract negotiations, design visit, detailed system design, utility rebate application, local rebate application, local rebate approval, building and electrical permit, local permits, schedule install, source and prepare system, installation, utility paperwork, utility inspection and new meter, utility rebate request, and local rebate request. Any of these steps may occur separately or in combination. In some embodiments, the steps may occur in the order as listed, while in other embodiments, the order of the steps may vary.

In some implementations, the surface of a typical residential sloped roof may be non-planar, with irregularities as large as several inches across distances spanned by solar arrays. A traditional installation may require careful layout and alignment of roof supports prior to attaching rails, which may be a cumbersome and time-consuming process. For example, a 1200 W system of six 200 W panels arranged in a 3×2 array will measure approximately 8′ across and 10′ tall, and will require four support rails resting on three posts each. In traditional systems, the twelve posts are accurately lined up, and then their heights are visually adjusted to ensure the support rails are straight.

The rack design of the invention may separate the fixed footings that may allow the system to rest on the roof, and the roof attachment points that can be adjusted along the sides of the rack. This may allow for an innovative efficient process of installing a module.

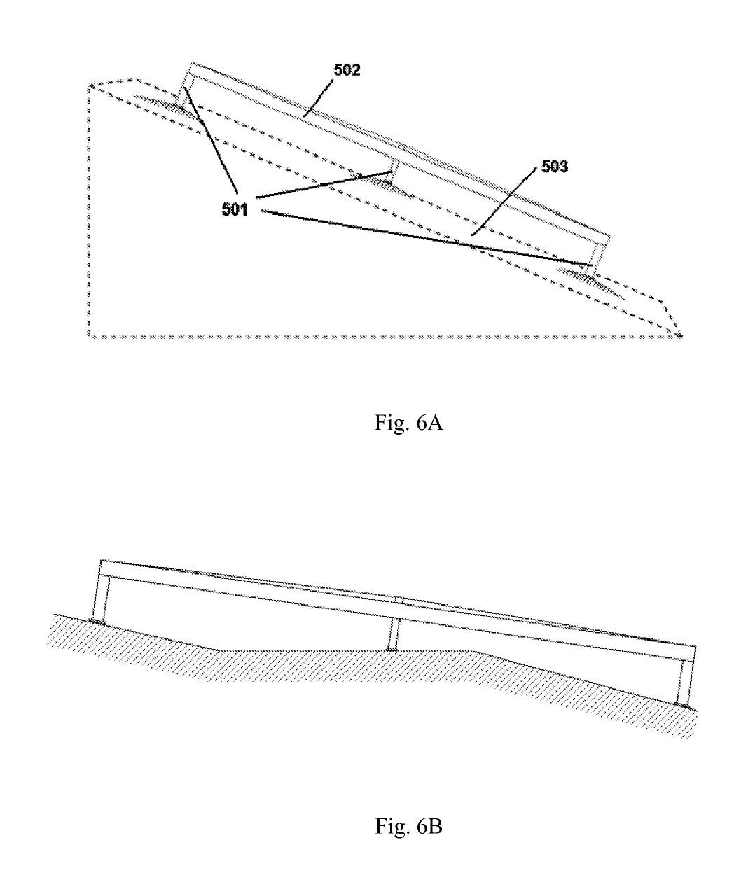

FIG. 6A shows how the rack design may include three footing points 501 on a triangular rack 502. Having three footing points 501 may enable the rack to stably rest on any uneven surface 503. Additionally, having three footing points may enable part of the rack (such as the sides) to be suspended over the surface. Suspended portions of the rack may not contact the surface.

FIG. 6B shows an additional view of a rack design that may include footing points resting on an uneven surface. By having three fixed footings, the rack may rest on a surface in a stable manner regardless of how even or uneven the surface is.

To install a module on a roof or other surface, an installer may mark the rafters or supports with a marker, such as a chalk line. The module may include a rack that is already assembled before being brought to the installment surface, or that may be assembled at the installment surface. The assembled triangular rack may not include panels when it is placed in a desired location. In a preferable embodiment of the invention, the footings may be fixed and the rack may just be placed on the desired location. In alternate embodiments, the length or placement of footings may be adjusted when the rack is at the desired location. In some embodiments, the footings may be fixed to the surface (e.g., bolted, stapled, nailed, screwed, adhered, clamped, etc.), while in other preferable embodiments, the footings may just rest upon the surface. The installer may then find the points where the rack sides pass over the rafters or any other support features.

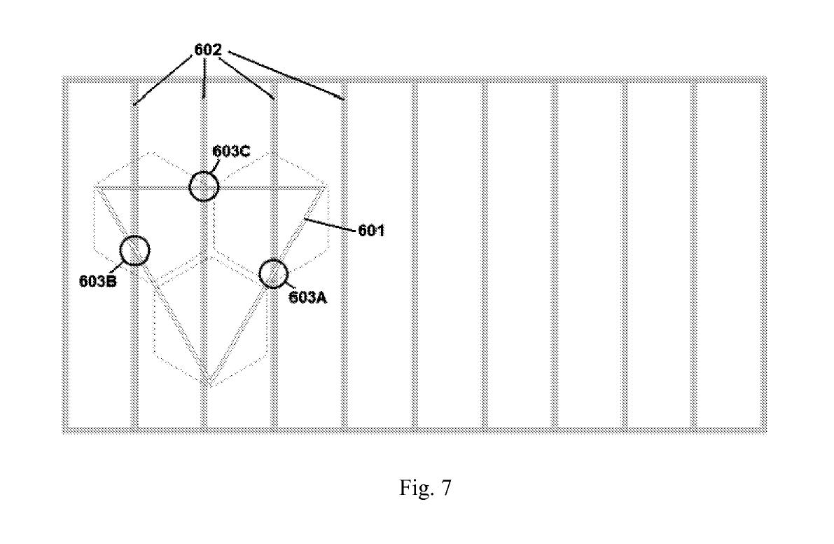

FIG. 7 shows an example of a rack 601 placed on a roof with underlying rafters 602 in accordance with one embodiment of the invention. In some instances, the rafters may be roof rafters with a standard spacing of 24″. There may be one or more possible rafter attachment points 603A, 603B, 603C. The rack 601 may be a triangular rack that crosses one or more rafters 602. The rack 601 may be fastened to a roof with roof fasteners. The roof fasteners may provide the roof attachment points 603A, 603B, 603C. The roof fasteners may slide along the side of the rack to secure the rack to the rafters. In some embodiments, roof fasteners may be placed anywhere on a rack without having to slide along the rack. For example a roof fastener may just be placed at the desired location and fastened to the surface accordingly.

The design of the rack may enable a reduced number of roof fasteners to be used to attach a rack to a surface. This may beneficially reduce the number of attachment points to the surface. In some instances, reducing attachment points may enable more rapid installation of the rack and may minimize any damage or any other effects on the surface.

In some embodiments, there may be three roof fasteners that may be slid along the rack to attach the triangular rack. For instance, there may be one roof fastener per side of a rack. Each roof fastener per side of the rack may slide to a point on the side of the rack that intersects a rafter. In another embodiment, some sides may not have a roof fastener. In some embodiments, multiple roof fasteners may be on one side, which may compensate for a deficiency on another side.

In other embodiments, there may be multiple roof fasteners per side. In some embodiments, a side of a rack may cross over more than one rafter. In order to have increased stability, it may be desirable to have multiple roof fasteners per side that can attach to a rafter. In instances where there may be multiple roof fasteners per side of rack, but the side may not pass over multiple rafters, a roof fastener may be idle, or may be removed from the rack, or moved to a location where it won't be in the way.

Furthermore, the length of the fasteners may be adjusted on the spot to match the distance between the surface of the roof and the rack rail. For example, the distance between the roof surface and the rack rail may vary along the rail. Thus, it is possible that there may be space between a roof surface and rack rail that may be the same or different for each of the fasteners. Thus, the length of the fastener may be adjusted to the desired length.

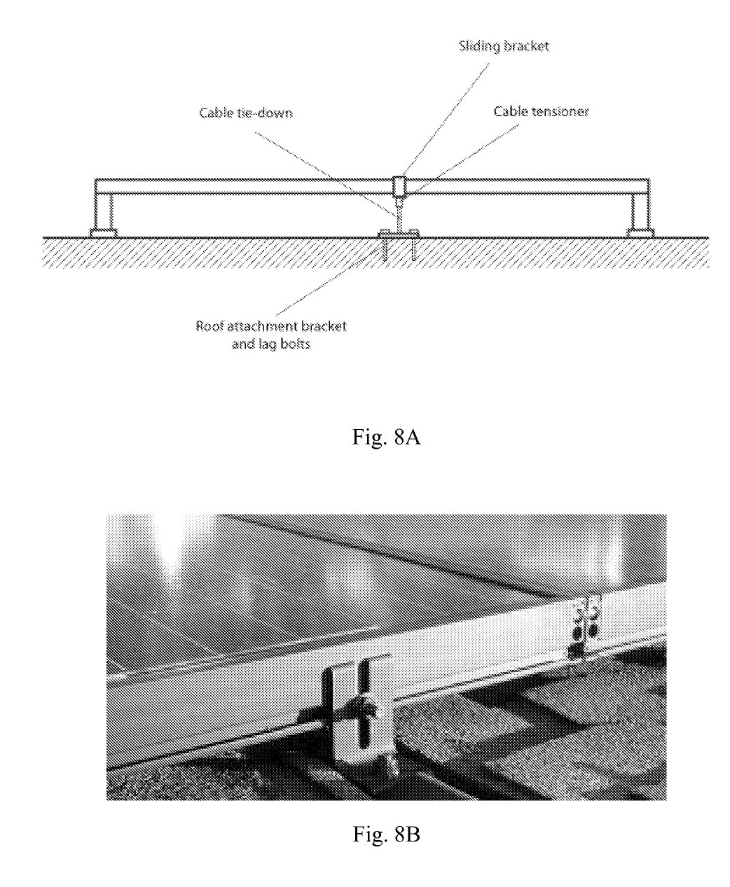

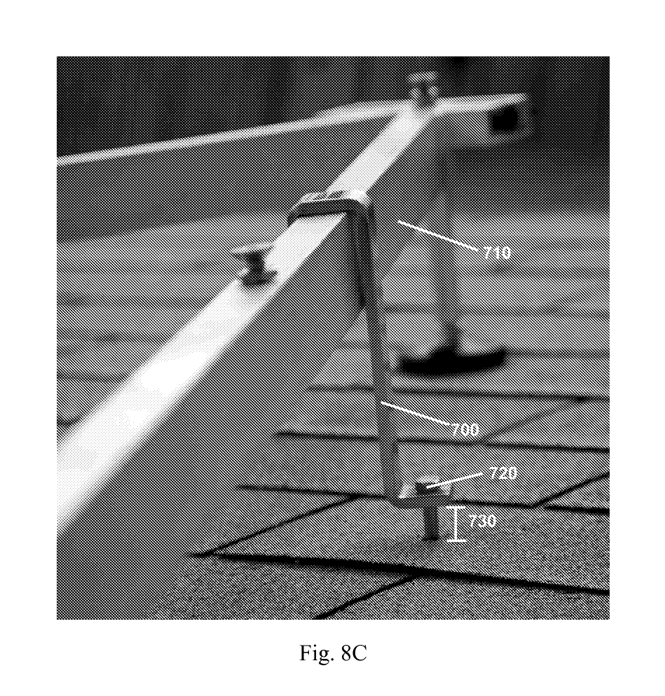

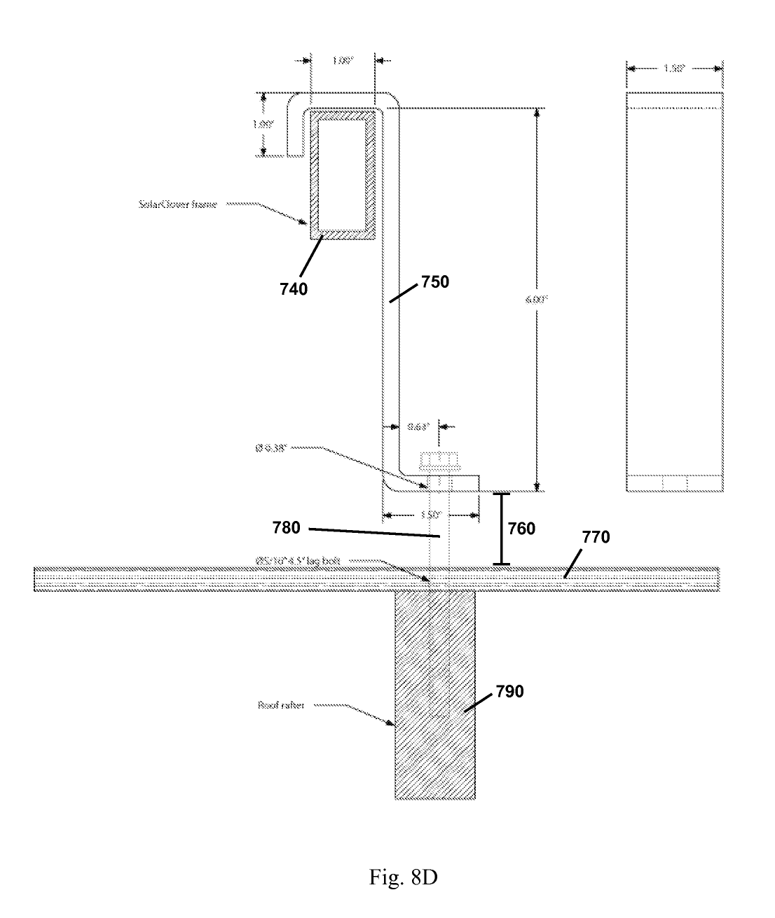

A fastener may have any configuration and/or structure that may enable the rack to be fastened to a surface. FIG. 8A provides one example of a fastener. For example, the fastener may slide over a side of a rack by using a sliding bracket. The fastener may also comprise a cable tensioner, a cable tie-down, and roof attachment bracket and lag bolts. The cable tensioner may enable the length of the cable to be adjusted, which may allow the fastener to have a desired tension to hold the rack in place. The fastener may be attached to a surface by using a roof attachment bracket and lag bolts. The bolts may fix the fastener to the surface. Other attachment means known in the art may be used, such as screws, nails, clamps, clips, adhesives, and so forth.

In one embodiment, the rack may be fastened to the roof by sliding the bracket to the desired attachment location along the side of the rack, bolting the bracket to the surface, and adjusting the length of the cable using the cable tensioner to achieve a desired tension. Alternatively, the rack may be fastened to the roof by sliding the bracket to the desired attachment location along the side of the rack, adjusting the length of the cable using the cable tensioner to achieve a desired length, and then bolting the roof attachment bracket to the surface.

FIG. 8B provides another example of a possible roof fastener. The length of the fastener may be adjusted by any means known in the art, including but not limited to allowing the fastener or a component thereof to slide to the desired length, adding or subtracting incremental portions of the fastener, or having predetermined points at which the fastener length may be adjusted. The fastener may be fastened to the surface, preferably along a rafter or other support. The fastener may be fastened by any means known in the art, including but not limited to mechanical fasteners such as bolts, screws, nails, clamps, adhesives, or locking or snapping mechanisms.

Thus, by having fasteners that may have an adjustable location along a rail and an adjustable length, the racks may be placed on a surface, even if the surface may be uneven or may have various features, and may be made to fit the location, rather than vice versa. This also provides a large amount of freedom in the placement of modules. Thus in situations where the roof may be irregularly shaped and there may have been problems adding solar panels to roofs before, the module may be able to accommodate various roof shapes or features. Thus, it may also be possible to cover a greater area of a roof.

A system may include three modules that may require a total of nine roof fasteners for a typical roof. Because the prior layout and alignment are not required, the installation may be easier, may take less time, and can be carried out by installers without special training.

FIG. 8C shows an example of a bracket fastener in accordance with another embodiment of the invention. A bracket 700 may hook over a side of a rack 710. The bracket may be connected to or affixed to a surface via a fastener 720. In some embodiments, the fastener may be a screw. The bracket may be positioned anywhere along the side of the rack. In some embodiments, the bracket may be positioned on the rack to be located above a roof rafter or other desired position on the surface, as described previously. A space 730 may be provided between the bottom of the bracket and the surface. This may be advantageously provided to allow the bracket to be tightened down with a fastener (e.g., lag screw), and may accommodate unevenness in the surface. In some embodiments, the brackets used may have the same length. Alternatively, the brackets used may be selected to have varying lengths to accommodate the surface if necessary. This may provide a simple, reliable, strong, and easy-to-install approach.

FIG. 8D shows a side view of a bracket fastener. A cross-sectional view of a rail 740 of a rack frame is shown. The rail cross-section may have any shape or size. For example, the rail cross-section may be a rectangle, square, triangle, circle, ellipse, trapezoid, pentagon, hexagon, octagon, or have any other regular or irregular shape. A bracket 750 may be configured to hook over the rail. Any dimensions are provided by way of example only, and any other dimensions may be used. In some examples, a bracket may be about 2 inches, 3 inches, 4 inches, 5 inches, 6 inches, 7 inches, 8 inches, 10 inches, or a foot long. The bracket may be shaped to match the cross-section of the rail. Alternatively, the bracket may be shaped to hook over the rail without having to match the cross-sectional shape of the rail. In some embodiments, the bottom portion of the bracket may be configured to extend away from the side hooking over the rail ('S′ configuration), which may provide ease in adding the fastener. Alternatively, the bottom portion of the bracket may extend below the rail ('C′ configuration), which may save space.

In some embodiments, a space 760 may be provided between a bottom of the bracket 750 and a surface 770. A fastener 780 may be used to connect the bracket to the surface. In some embodiments, the fastener may be a screw, such as a lag screw. Optionally, the surface may have an underlying support 790. For example, if the surface is a roof, the underlying support may be a roof rafter. The fastener may penetrate the surface and/or underlying support. In some embodiments, the bracket may be tightened using the fastener. This may accommodate even or uneven surfaces, and allow the rack to be securely fastened to the surface.

IV. Integrated Microinverters

The solar panel system may include microinverters. Rather than requiring a microinverter per panel, the system may use a single microinverter per each module. This may reduce the number of components and cost, while still providing an integrated system with AC output.

The microinverter may be incorporated into a module in any manner. For example, the microinverter may be attached to a rack of the module. FIG. 1D shows one example of how a microinverter 123 may be attached to the rack 122 on the underside of each module. The microinverter may be attached to the rack on a portion of the rack inside the shape delineated by the rack, or outside the shape delineated by the rack, or within a rack rail itself.

In one example, the microinverter 123 may be attached to the rack 122 on the inside of the shape delineated by the rack, and may be supported by support features 124. A microinverter support or housing may have any shape and may be attached to the rack in any manner. In some examples, support features 124 or any other portion of the rack or housing may provide electrical connections between the microinverter and the rest of the electrical features in the rack.

In alternate embodiments of the invention, a plurality of microinverters may be provided per module and may be integrated into a rack. In some cases, the plurality of microinverters may be used concurrently. In other cases, one microinverter may be in operation while another may be provided as a backup.

In other alternate embodiments of the invention, a microinverter may be provided for a solar panel system. The microinverter may be electrically connected to solar panels of a plurality of modules. In such a situation, some modules may not include a microinverter while some modules may.

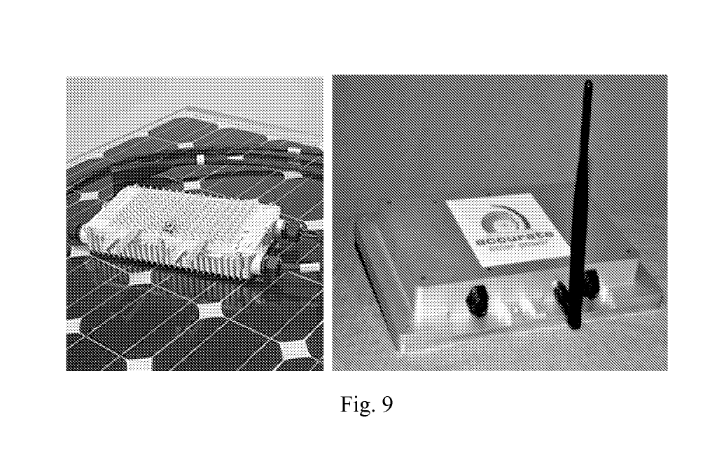

Any microinverter known in the art or later developed may be used. For example, a commercially available microinverter, such as a system from Enphase or Accurate Solar Power may be used (examples shown in FIG. 9). A module may require a microinverter capable of handling 400 W input power. Any other microinverter that may be conceived or applied may be used. Due to continuous increase of output power of new models of solar panels, as well as requirements for larger microinverters from thin-film manufacturers producing large modules, inverter sizes and input capabilities may foreseeably increase.

A microinverter may be selected to have desirable features. For example, a microinverter may be able to handle 500 W or greater, 450 W or greater, 400 W or greater, 350 W or greater, or 300 W or greater. A microinverter may have a desirable a power output of 450 W. In some instances, a microinverter may have a voltage range that may preferably fall within 40-100 V. A microinverter may also preferably have MPPT tracking capabilities. A microinverter may be selected to have any of these desired features.

Integrating microinverters into the system may improve efficiency and resilience to partial shading. Such resilience may be improved by the use of Maximum Power Point Tracking (MPPT). MPPT may be a DC to DC converter which may function as an optimal electrical load for a PV cell, and may convert the power to a voltage or current level which is more suitable to whatever load the system is designed to drive. For instance, PV cells may have a single operating point where the values of the current and voltage of the cell may result in a maximum power output. MPPT may utilize some type of control circuit or logic to search for this point and may thus allow the converter circuit to extract the maximum power available from a cell.

In one example, if an inverter is battery-less and grid-tied, it may utilize MPPT to extract the maximum power from a PV array, convert the power to AC, and sell excess energy back to the operators of the power grid.

In another example, an off-grid power system may also use MPPT charge controllers to extract the maximum power from a PV array. When the immediate power requirements for other devices plugged into the power system are less than the power currently available, the MPPT may store the “extra” energy (i.e., energy that is not immediately consumed during the day) in batteries. When other devices plugged into the power system require more power than is currently available from the PV array, the MPPT may drain energy from those batteries in order to make up the lack.

In addition, the microinverters may have built-in performance reporting functions. Such performance reporting functions can operate in communication with a performance monitoring dashboard, as discussed previously. In some embodiments, such performance reporting functions can be provided wirelessly, such as over a ZigBee low-power wireless link (Accurate Solar Power) or AC powerline (Enphase). The performance reporting function may be used in conjunction with providing a performance reporting website. A user may remotely access the performance reporting website to view the performance of the system, individual modules, or solar panels.

V. Integrated Electrical and Mechanical Design

Traditional residential PV systems using a single inverter per solar panel may require careful DC design and DC wiring from the panel to the inverter. The installers must also properly connect each panel after it is installed on the roof, paying attention to DC polarity and required string design. Typical licensed electricians who are not experienced in solar installations deal primarily with AC wiring and the associated specialty components in their daily work. Traditional solar panels also impose special grounding requirements.

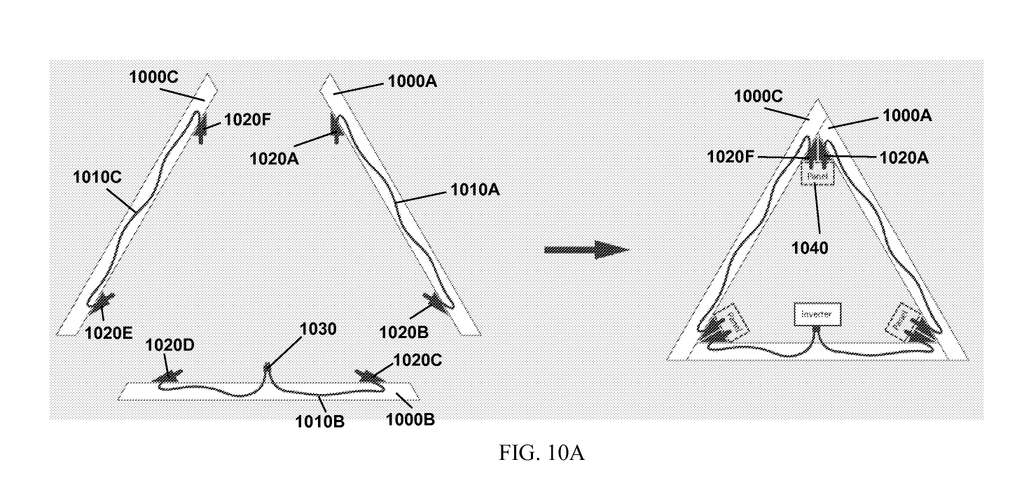

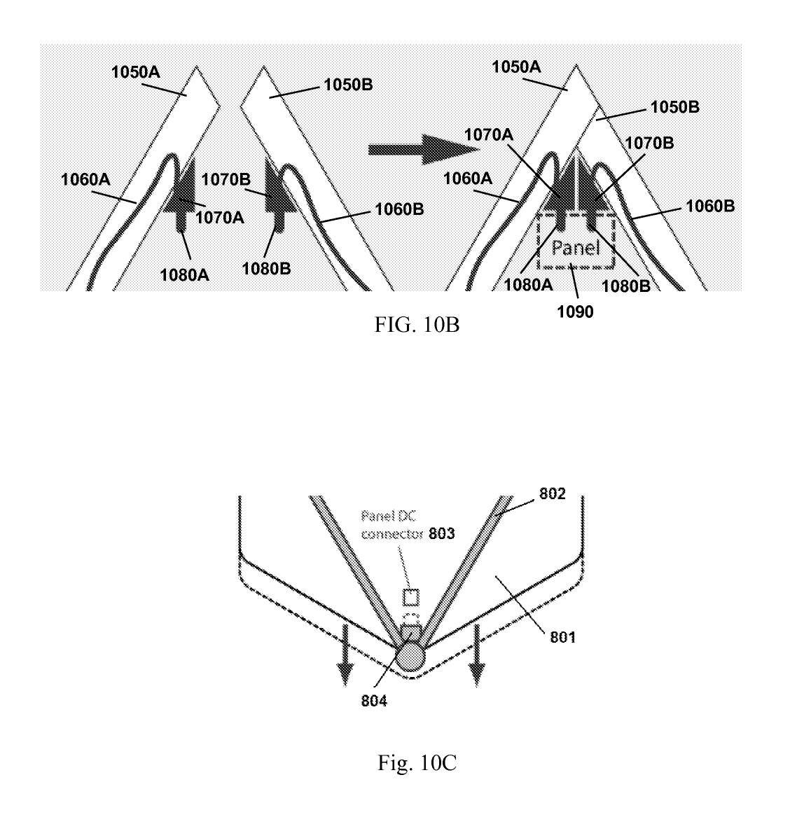

FIG. 10A shows an example of a rack with a plurality of rack sections 1000A, 1000B, 1000C. In some embodiments, a rack section may be a rail. The rail may form a side of the rack. For example, if the rack has a triangular shape, three rails may be provided. In other embodiments, rack sections may be any portion of the rack which may include a part of a side of the rack, a side of the rack, or a plurality of sides of the rack.

In some embodiments, wiring 1010A may be routed with the rack rails 1000A so that no wires need to pass between the rails. Each rail 1000A, 1000B, 1000C may have wiring 1010A, 1010B, 1010C that is provided with that rail alone. This may enable the wiring to be installed at the manufacturer factory, and may eliminate the need to connect individual cables by the installer onsite. Preferably, the wires may pass within the rack rails, although they may alternatively be exterior to the rack rails. The wiring may have one, two, or more connector 1020A, 1020B. Preferably, the connectors may be located at or near the end of the rail, although in other embodiments they may be located elsewhere. In some embodiments, two end connectors may be provided per rail, such that a first end connector 1020A is located near or at a first end of a rail, and the second end connector 1020B is located near or at a second end of the rail.

In some embodiments, each of the rails, wiring, and end connectors within a rack may be the same. Alternatively, the rails may vary. In some embodiments, one or more rails may include an additional connector. The additional connector may connect to an inverter. In some embodiments, one inverter connector 1030 may be provided per rack. An inverter connector may be located anywhere along a rail (e.g., towards middle of rail, towards an end of the rail).

The rails may be connected to form a rack, as shown on the right section of FIG. 10A. A first connector 1020A may be connected to the wiring 1010A of a first rack section 1000A and a second connector 1020F may be connected to the wiring 1010C of a second rack section 1000C. The first connector and the second connector may form a plug configured to accept a solar panel. The plug may be inserted into an interface of the solar panel 1040.

FIG. 10B shows a close up of a corner split plug. The corner split plug may be formed of a first end connector 1070A and a second end connector 1070B. The first end connector may be electrically connected to a first set of wiring 1060A within a first rail 1050A, and the second end connector may be electrically connected to a second set of wiring 1060B within a second rail 1050B. In some embodiments, each end connector may have a prong 1080A, 1080B, or other interface for electrical connection. Thus, a corner split plug may include a plurality of end connectors and plurality of prongs. The plug may be inserted into an electrical interface for a solar panel 1090. In other embodiments, electrical connection with the plurality of end connectors and solar panel may be established in any other manner (e.g., the solar panel may have prongs that may be inserted into the end connectors).

The rack system may have any other wiring configuration. In some embodiments, the end connectors may be provided at the end of the rails so that when the rails are physically connected to one another, they are also electrically connected to one another without requiring wiring to pass between the rails. Or in alternative configurations, wiring may pass between the rails. In some instances, the wiring in different rails may be electrically connected to one another through the solar panel interface. Alternatively, they may be directly electrically connected to one another. The wiring may enable the solar modules on the rack to be connected in series to a microinverter. Alternatively, the solar modules may have any other connection to the microinverter (e.g., series, parallel, or combination thereof).

The solar panel system design of the invention may integrate the DC electrical connections into the module rack in such a manner that installers may only insert a panel into the rack and slide it into place to establish the electrical connection between the panel and microinverter.

FIG. 10C shows one example of how a panel 801 may slide into a rack 802 and form an electrical connection. The figure may provide an underside view of a module during panel installation. Sliding the panel 801 into place may establish an electrical connection between the panel and integrated wiring inside the rack 802. Each of the panels of a module may have an interface for electrical connections. For example, the interface may be a panel DC connector 803. The connector 803 may slide with the panel 801 to make contact with a portion of the rack that provides electrical connectivity 804.

A solar panel may attach to a rack in any way known in the art. For example, sliding a panel into place may be a preferable embodiment of the invention. However, a solar panel may also snap into place, lock into place, twist into place, be fastened into place or may contact a rack any other way known in the art. When a solar panel is attached to a rack, it may form an electrical connection between the panel and integrated wiring and/or microinverter.

Allowing a simple interconnection may reduce DC wiring errors and may allow installers to work exclusively with AC wiring, which may make the installation more accessible to electricians without specialized solar training. Thus, after a rack has been fastened to a roof, one or more solar panels may slide into the rack, providing DC connections. Then, only AC wiring, such as those between modules, or directly to a grid may be done.

Within a system, solar modules may be connected to a utility grid. Alternatively, solar modules may operate in a grid-less manner and may include batteries that may store energy. Solar modules may also include a communications component that may enable solar modules to communicate with a control and/or monitoring system. The solar modules may communicate with the control/monitoring system through a wire, or may communicate wirelessly. One or more control/monitoring interfaces or modules may communicate with one another over a network. In some embodiments, the network may be a local area network, or a wide area network, or the Internet.

A user may be able to interact with a control/monitoring system at any level of interaction. For example, a user may access a central control system and control or monitor the conditions relating to the solar modules at any level. In some embodiments, a user may access a central control system through a user interface, which may be provided by a computer, PDA, phone, laptop, or any other network device. The user interface may display a performance reporting website or performance monitoring dashboard. In some embodiments, a user interface may be integrated with a structure of a module.

VI. Low Weight, Classless, Frameless Panels

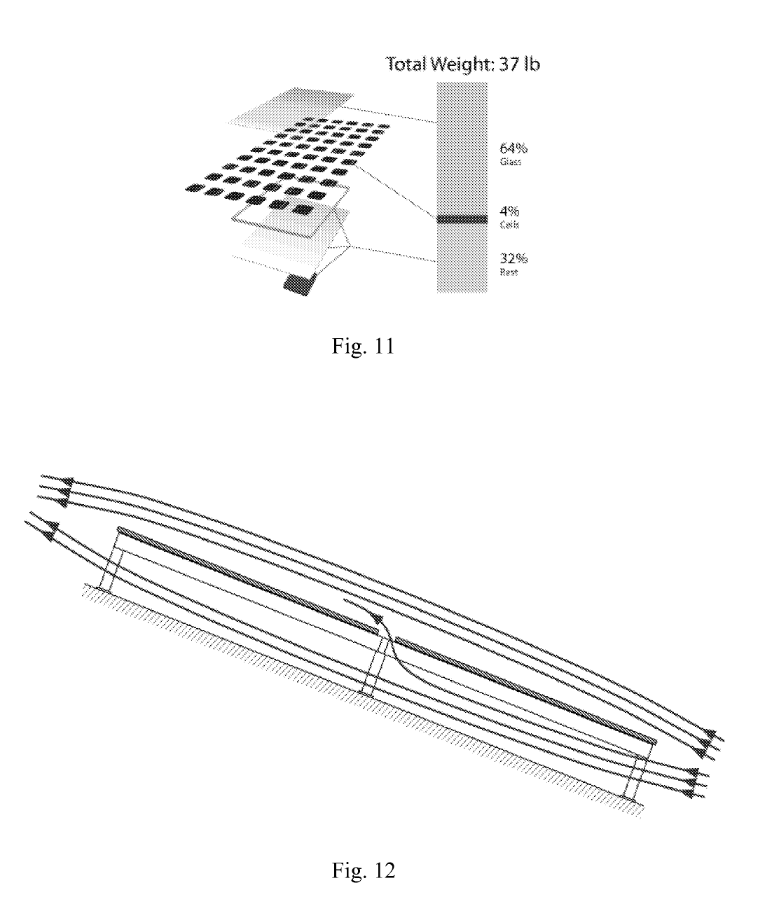

In a traditional crystalline silicon panel, the glass top sheet and the aluminum frame may account for the majority of its weight. FIG. 11 shows an example of a breakdown of the weight of a traditional solar panel. Furthermore, grounding traditional panels presents an additional challenge to installers, because of poor contact between aluminum frame and copper grounding wire. In some embodiments of the invention, the solar panel system may use a traditional solar panel.

However, in accordance with a preferable embodiment of the invention, the solar panel system provided by the invention may use polymer panels. The polymer panels may have no exposed metal parts and may not require grounding. This may improve safety, may simplify installation, and may reduce specialized expertise requirements from installers.

Any material may be used to form a solar panel. In preferable embodiments, the material may be a polymer, although traditional solar panel materials may also be used in combination with other aspects of the invention. One example of a polymer that may be used is a fluoropolymer such as ethylene tetrafluoroethylene (ETFE). Some example of such may be Tefzel ETFE film, Fluon ETFE, Neoflon ETFE, and Texlon ETFE. This may be an attractive option for use as the top sheet due to its high transmissivity and longevity. For instance, the material for a solar panel may preferably have high corrosion resistance and strength over a wide temperature range. The material may also be lightweight compared to glass. For instance, ETFE film may be 1% the weight of glass, may transmit more light, and may costs 24% to 70% less to install. The solar panel material may also preferably be resilient (e.g., ETFE may be able to bear 400 times its own weight), self-cleaning (e.g., ETFE may have a nonstick surface), and/or recyclable. Several commercial solar products have successfully used Tefzel in solar panels, including Lumeta PowerPly crystalline silicon modules and Uni-Solar PV laminates.

Other polymers that may be used include, but are not limited to bakelite, neoprene, nylon, PVC, polystyrene, polyacrylonitrile, PVB, silicone, or other fluoropolymers. Some examples of additional fluoropolymers may include PTFE (polytetrafluoroethylene) Teflon, Algoflon, or Polymist; PFA (perfluoroalkoxy polymer resin) Teflon or Hyflon; FEP (fluorinated ethylene-propylene) Teflon; PVF (polyvinylfluoride) Tedlar; ECTFE (polyethylenechlorotrifluoroethylene) Halar; PVDF (polyvinylidene fluoride) Kynar, Solef, or Hylar; PCTFE (Kel-F, CTFE) (polychlorotrifluoroethylene); FFKM Kalrez or Tecnoflon; FPM/FKM Viton or Tecnoflon; PFPE (perfluoropolyether) Fomblin or Galden.

A solar panel may utilize conventional crystalline silicon cells, or any other types of solar cells, as discussed previously. The solar panel may also include a bonded polymer topsheet, such as Tefzel. Additionally, the solar panel may also include a stiff polymer backing that might use corrugated plastic structures. Furthermore, integrated rack attachment components may also be included, which may or may not be formed of a polymer. Any of these components may be combined with one another or traditional solar panel components.

VII. Wind Loading

Wind loading codes may impose high requirements on the strength of roof attachments. For example, a single module, with a surface area of 26 square feet, may experience 780 lb of pull, assuming a wind load parameter of 30 lb/square feet at 110 mph. A solar module with a different surface area, or differing wind load parameters may result in a different amount of wind pull.

The module design may optionally account for wind load. For example, the spaces between the panels of the modules may be arranged to desirably control the wind load. In some embodiments, the amount of space between the modules may be increased or decreased to allow wind flow, and to reduce wind pull. Other factors that may come into play for a module design for wind loading may include panel shapes or dimensions, spacing, tilt, and/or profile. The spacing of the modules may also be desirably provided to provide cooling to the various components of the module, including the electronics of the rack and/or the solar panel.

FIG. 12 shows a cross section view of a module and an example of how wind may flow. For example, wind may flow above and below a solar module. In some instances, the wind flow may be predominantly laminar flow. In other embodiments, the wind flow may be turbulent. In some embodiments of the invention, wind may flow between spacing provided by the panels. For example, wind may flow beneath a solar panel, and then flow above another solar panel. Alternatively, wind may flow above a solar panel, and then flow beneath another solar panel. In some embodiments, allowing wind to flow through a gap between panels may reduce wind loading on a solar module.

The solar panel configurations can be used in conjunction with various commercial packages or with analysis components. For example, a solar shade analysis system may be used to predict the expected output of a solar photovoltaic system. Shade analysis tools may be used during installation of the solar panels. A shade analysis system may be included with the solar panels as part of a commercial mass-market package.

It should be understood from the foregoing that, while particular implementations have been illustrated and described, various modifications can be made thereto and are contemplated herein. It is also not intended that the invention be limited by the specific examples provided within the specification. While the invention has been described with reference to the aforementioned specification, the descriptions and illustrations of the preferable embodiments herein are not meant to be construed in a limiting sense. Furthermore, it shall be understood that all aspects of the invention are not limited to the specific depictions, configurations or relative proportions set forth herein which depend upon a variety of conditions and variables. Various modifications in form and detail of the embodiments of the invention will be apparent to a person skilled in the art. It is therefore contemplated that the invention shall also cover any such modifications, variations and equivalents.

What is claimed is:

1. A rack for a solar module comprising:
three footings that are configured to contact a surface; a plurality of fasteners configured to fasten the rack to the surface; and a microinverter attached to the rack, wherein the rack is configured to accept a plurality of solar panels.

2. The rack of claim 1 wherein the rack forms a triangle.

3. The rack of claim 1 wherein the solar panels have a hexagonal shape.

4. The rack of claim 1 wherein at least one of the plurality of fasteners comprises a cable tie-down.

5. The rack of claim 1 wherein at least one of the plurality of fasteners comprises a bracket.

6. The rack of claim 1 wherein at least one of the position of the plurality of the fasteners or the length of the plurality of fasteners is adjustable.

7. A solar module comprising:
a triangular rack comprising three footings, a plurality of fasteners to fasten the rack to a surface, and at least one microinverter electrically connected to the rack and to an electrical connector interface; and
a plurality of solar panels configured to electrically connect to the electrical connector interface.

8. The solar module of claim 7 wherein the plurality of solar panels comprise a polymer.

9. The solar module of claim 7 wherein the rack includes a plug with a first connector connected to a first set of wiring and a second connector connected to a second set of wiring.

10. The solar module of claim 9 wherein the first set of wiring is within a first side of the rack, and the second set of wiring is within a second side of the rack.

11. The solar module of claim 7 wherein the solar panels have a hexagonal shape.

12. A method of installing a solar module comprising:
placing a rack with three footings and at least one microinverter on a desired surface at a desired location;
determining if the position of one or more fasteners is to be adjusted and adjusting if desired;
determining if the length of one or more fasteners is to be adjusted and adjusting if desired;
fastening the fastener to the surface;
attaching at least one solar panel to the rack; and
establishing an electrical connection between the solar panel and the at least one microinverter.

13. The method of claim 12, wherein the solar panel slides into a corner of the rack.

14. The method of claim 12, wherein the fastener is a bracket.

15. The method of claim 14, wherein the fastener is tightened to a surface with a screw.

16. The method of claim 12, wherein the rack is has a plurality of rails forming the sides of the rack.

17. The method of claim 16, wherein the rack does not have wiring passing between the rails.

18. A rack for a solar module comprising:
a plurality of rack sections, wherein a first rack section has wiring with a first connector and a second rack section has wiring with a second connector, wherein the first and second rack sections are connected to one another, and wherein the first connector and the second connector form a plug configured to connect to a solar panel.

19. The rack of claim 18 having three rack sections.

20. The rack of claim 19 wherein each rack section has wiring and at least two connectors.

21. The rack of claim 18 further comprising three footings.

22. The rack of claim 18 wherein the wiring of at least one rack section is connected to an inverter.
